(19) United States
(12) Patent Application Publication
(10) Pub. No.: US 2015/0047687 A1
(43) Pub. Date: Feb. 19, 2015

(54) PREPARATION AND COATING OF THREE-DIMENSIONAL OBJECTS WITH ORGANIC OPTOELECTRONIC DEVICES INCLUDING ELECTRICITY-GENERATING ORGANIC PHOTOVOLTAIC FILMS USING THIN FLEXIBLE SUBSTRATES WITH PRESSURE-SENSITIVE ADHESIVES

(71) Applicants: John Anthony CONKLIN, Apalachin, NY (US); Scott Ryan HAMMOND, Wheat Ridge, CO (US)

(72) Inventors: John Anthony CONKLIN, Apalachin, NY (US); Scott Ryan HAMMOND, Wheat Ridge, CO (US)

(73) Assignee: New Energy Technologies, Inc., Columbia, MD (US)

(21) Appl. No.: 14/317,972

(22) Filed: Jun. 27, 2014

Related U.S. Application Data
(60) Provisional application No. 61/841,243, filed on Jun. 28, 2013.
(60) Provisional application No. 61/842,355, filed on Jul. 2, 2013.
(60) Provisional application No. 61/841,244, filed on Jun. 28, 2013.
(60) Provisional application No. 61/842,357, filed on Jul. 2, 2013.
(60) Provisional application No. 61/841,247, filed on Jun. 28, 2013.
(60) Provisional application No. 61/842,365, filed on Jul. 2, 2013.
(60) Provisional application No. 61/841,248, filed on Jun. 28, 2013.
(60) Provisional application No. 61/842,372, filed on Jul. 2, 2013.
(60) Provisional application No. 61/842,796, filed on Jul. 3, 2013.
(60) Provisional application No. 61/841,251, filed on Jun. 28, 2013.
(60) Provisional application No. 61/842,375, filed on Jul. 2, 2013.
(60) Provisional application No. 61/842,803, filed on Jul. 3, 2013.

(51) Int. Cl. H01L 51/00

(52) U.S. Cl. CPC H01L 51/0097; H01L 51/0013; H01L 51/003; H01L 51/0096
USPC 136/244; 438/82; 136/252

(57) ABSTRACT

A general method for the fabrication of three-dimensional objects of arbitrary shapes coated in organic optoelectronic devices, including semitransparent objects and optoelectronic devices, is described. In particular, a method for fabricating curved objects coated in organic photovoltaic, and especially semitransparent photovoltaic, devices is presented. High-throughput and low-cost fabrication options also allow for economical production.

### CROSS-REFERENCE TO RELATED APPLICATIONS

This application claims priority under 35 U.S.C. 119(e) of U.S. Provisional Application No. 61/841,243, filed on Jun. 28, 2013 (Attorney Docket No. 7006/0141PR01), U.S. Provisional Application No. 61/842,355, filed on Jul. 2, 2013 (Attorney Docket No. 7006/0141PR02), U.S. Provisional Application No. 61/841,244, filed on Jun. 28, 2013 (Attorney Docket No. 7006/0142PR01), U.S. Provisional Application No. 61/842,357, filed on Jul. 2, 2013 (Attorney Docket No. 7006/0142PR02), U.S. Provisional Application No. 61/841,247, filed on Jun. 28, 2013 (Attorney Docket No. 7006/0143PR01), U.S. Provisional Application No. 61/842,365, filed on Jul. 2, 2013 (Attorney Docket No. 7006/0143PR02), U.S. Provisional Application No. 61/841,248, filed on Jun. 28, 2013 (Attorney Docket No. 7006/0144PR01), U.S. Provisional Application No. 61/842,372, filed on Jul. 2, 2013 (Attorney Docket No. 7006/0144PR02), U.S. Provisional Application No. 61/842,796, filed on Jul. 3, 2013 (Attorney Docket No. 7006/0145PR01), U.S. Provisional Application No. 61/841,251, filed on Jun. 28, 2013 (Attorney Docket No. 7006/0146PR01), U.S. Provisional Application No. 61/842,375, filed on Jul. 2, 2013 (Attorney Docket No. 7006/0146PR02) and U.S. Provisional Application No. 61/842,803, filed on Jul. 3, 2013 (Attorney Docket No. 7006/0147PR01); the entire contents of all the above identified patent applications are hereby incorporated by reference in their entirety. This application is related to Applicants' co-pending U.S. applications, which are filed concurrently herewith on Jun. 27, 2014, 7006/0141PUS01, 7006/0142PUS01, 7006/0143PUS01, 7006/0144PUS01, 7006/0145PUS01, and 7006/0147PUS01; each of which is incorporated herein by reference in its entirety.

### FIELD OF THE INVENTION

The present invention is directed to a method for the preparation and coating of three-dimensional objects with organic optoelectronic devices, including electricity-generating organic photovoltaic films, using thin, highly flexible substrates with pressure-sensitive adhesives, and more particularly, to doing so with semi-transparent organic photovoltaic films for see-through applications.

### BACKGROUND OF THE INVENTION

Processes for coating of three-dimensional objects are very limited in nature and scope. While coating of three-dimensional objects of arbitrary shapes is possible, via such coating techniques as: dip, curtain, rotating drum/fluidized bed, and spray, these techniques cannot provide the precise control of coating thickness, uniformity, and coverage required for organic optoelectronic devices such as organic photovoltaic (OPV), organic light-emitting diode (OLED), or organic electronic devices, such as organic thin-film transistors (OTFT). The science and technology of precise, thin film coating has mainly focused on planar surfaces, largely due to the issues with capillarity flow of fluids at curved surfaces.

### SUMMARY OF THE INVENTION

Despite the limitations in precisely coating three-dimensional objects, for a number of applications it would be desirable to prepare such objects with various optoelectronic devices. In particular, it would be desirable for a number of applications to be able to prepare OPV devices, and especially semi-transparent OPV devices, on curved surfaces and non-planar discrete objects. For example, it would be desirable to prepare semi-transparent OPV devices on curved window surfaces for application in military and commercial aircraft windows, which are the subject of Applicants' related applications entitled “Coatings for Aircraft Window Surfaces to Produce Electricity for Mission-Critical Systems on Military Aircraft”, “Coatings for Aircraft Fuselage Surfaces to Produce Electricity for Mission-Critical Systems on Military Aircraft”, “Coatings for Aircraft Window Surfaces to Produce Electricity for Mission-Critical Systems and Maintenance Load on Commercial Aircraft”, and “Coatings for Aircraft Fuselage Surfaces to Produce Electricity for Mission-Critical Systems and Maintenance Load on Commercial Aircraft”.

Arguably the most sophisticated technique for coating curved and other three-dimensional objects is spray coating, which has long been used for macro-scale coating of curved and three-dimensional objects such as auto body parts. Spray coating has also been used to precisely coat planar substrates for optoelectronic devices, particularly OPV devices, which require highly uniform thin films on the order of 100-200 nm. Despite this, the precise spray coating of curved and three-dimensional objects for optoelectronic devices, and particularly OPV devices, remains an attractive but elusive goal. As previously mentioned, the realities of capillarity flow at curved surfaces is the main barrier; fluids on curved surfaces are pumped away from the curvature by capillarity flow. If the object has uniform curvature, then capillarity flow is minimized and the main challenge becomes uniform application of fluid, which can be achieved by carefully controlled spray head movement. But for any object with varying curvature will always be subject to the effects of capillarity flow, regardless of the coating method.

OPV is an inherently flexible technology, however, which opens up new possibilities for obtaining three-dimensional coated objects. For example, Kaltenbrunner et. al (Nature Comm. DOI: 10.1038/ncomms1772) has demonstrated that by using very thin substrates, supported with temporary substrates and coated via conventional spin coating techniques, very flexible OPV devices can be prepared with comparable performance to those produced on rigid substrates, and the devices can survive extreme elastic deformations. The present application recognizes that the properties described by Kaltenbrunner et. al (Nature Comm. DOI: 10.1038/ncomms1772) can be adapted and taken advantage of to provide a novel method of production of three-dimensional optoelectronic devices, which is the subject of the exemplary embodiments of the present invention described herein.

The present invention recognizes that conventional methods for coating curved and three-dimensional objects lack the precision required for preparation of organic optoelectronic devices, particularly for the manufacture of OPV and semi-transparent OPV devices. It also recognizes that preparation of curved and three-dimensional objects coated with optoelectronic devices, and in particular OPV and semi-transparent OPV devices, is desirable for a number of applications.

These problems and others are addressed by the present invention, a first exemplary embodiment of which comprises a method for the preparation of curved and otherwise three-dimensional objects with thin organic optoelectronic devices attached to their surfaces. The method involves a very thin, flexible substrate, such as a thin polymer foil, supported by a more rigid backing material, if necessary, which may include transfer release layers. The optoelectronic device of interest may then be fabricated directly on the substrate using standard methods know to those skilled in the art, including such precision coating techniques as: spray, curtain, slot-die, gravure, etc. In some embodiments, the surface of the optoelectronic device may then be coated in an appropriate pressure-sensitive adhesive (PSA), while in other embodiments the PSA may be located between the flexible substrate and the more rigid backing material. In some embodiments, the completed optoelectronic device and flexible substrate may be transferred to a new rigid backing material with a transfer release layer, if necessary, in contact with the top of the completed optoelectronic device. The bottom rigid support material may then be removed, and a PSA can be applied directly to the thin flexible substrate using conventional coating techniques know to those skilled in the art. In any of the above embodiments, the PSA-coated surface may then be used to adhere the optoelectronic device and thin substrate to the curved or three-dimensional object by stretching and press-forming, or related techniques, with or without an applied vacuum to assist in removal of entrained air between the PSA and the object. In such a manner, an optoelectronic device may be coated in a planar fashion using conventional precision coating techniques, in a manner that is compatible with high-throughput production techniques such as roll-to-roll manufacturing, and then stretched and adhered onto a curved or three-dimensional object in a batch process. This method avoids the inherent fluid dynamics limitations in coating curved and discrete objects, maximizes production throughput, and allows production of unique optoelectronic devices.

In the above embodiments, the optoelectronic device may be any of a number of different technologies, including but not limited to: OPV and semi-transparent OPV devices (cells or modules), OLEDs, or organic electronic devices such as OTFTs. The only requirement for such technologies is that they be inherently flexible, which generally restricts the use to amorphous and semi-amorphous solids, including glasses and gels. Many of the materials in organic optoelectronic devices are polymers and molecular glasses, which are amorphous materials. A common class of material in many optoelectronic devices is a transparent conductor (TC), which provides sufficient conductivity to allow vertical and lateral charge transport, while allowing most light to pass through. The most common TC material by far is the transparent conductive oxide (TCO) indium tin oxide (ITO), which is a crystalline, doped metal oxide material with favorable conductivity and visible light transmission (VLT) properties. Because of its crystalline nature, however, ITO is readily cracked on flexing, which causes catastrophic loss of conductivity. As such, ITO is not compatible with the present invention, and all optoelectronic devices fabricated using this method cannot incorporate it. There are a number of alternative TC materials that may be used in optoelectronic devices used in this invention, including but not limited to: conductive polymers, such as highly doped poly(ethylenedioxythiophene):poly(styrenesulfonate) [PEDOT:PSS]; metal nanowire or carbon nanotube meshes; continuous graphene sheets or small overlapping graphene sheets; amorphous TCOs such as aluminum-doped zinc oxide (AZO), gallium-doped zinc oxide (GZO), or indium-doped zinc oxide (IZO); or any combinations thereof. The afore-mentioned flexible-compliant TC materials are provided for descriptive purposes only, and are not meant to be exhaustive in nature. The manner of use of these TC materials is described in Applicants' realted applications, including for example “TRANSPARENT CONDUCTIVE COATINGS FOR USE IN HIGHLY FLEXIBLE ORGANIC PHOTOVOLTAIC FILMS ON THIN FLEXIBLE SUBSTRATES WITH PRESSURE-SENSITIVE ADHESIVES.”

Another exemplary embodiment of the invention comprises a method for the fabrication of a three-dimensional object with an OPV device (cell or module) attached to its surface. A thin flexible substrate, such as a thin polymer foil, is attached to a more rigid yet still somewhat flexible support layer, such as a thick polymer foil, via a transfer release layer. The thin substrate is then coated with a TC material, such as the conducting polymer PEDOT:PSS, or an amorphous TCO such as AZO via methods known to those skilled in the art. The TC layer is then coated with the remainder of the layers of an OPV device, as is known to those skilled in the art of OPV. In some embodiments, the OPV device may be a conventional architecture OPV device, while in others it may be an inverted architecture OPV device. In either case, the photoactive layer may be the same, and is generally comprised of a bulk heterojunction (BHJ) between an electron donor, often a polymer, and an electron acceptor, often a fullerene. Other layers that may be included are electron- and hole-collection layers (ECL and HCLs, respectively), which can include of amorphous metal oxides and/or polymers, all of which are inherently flexible. The appropriate locations for such layers depend on the architecture of the OPV device, and are known to those skilled in the art. In all of the exemplary cases, the final layer of the OPV device includes a ductile top metal electrode, such as silver, which can be deposited via a number of methods, from screen-printing to evaporation, some of which are compatible with high-throughput, roll-to-roll manufacturing methods (e.g. rotary screen printing). In some embodiments, when the device being fabricated is a module, there may be additional processing steps, such as laser and/or mechanical scribing, to allow fabrication of series and/or parallel interconnected devices. In some embodiments, these steps may be located in between device layer deposition steps, and in some embodiments, these may be performed at the end. After the OPV device is completed, a PSA is applied to the surface of the device using coating techniques as known to those skilled in the art. The thin, flexible substrate along with the completed OPV device and PSA are then removed from the rigid substrate using the release layer, and stretched and press-fit onto the curved or three-dimensional shape, with or without vacuum-assisted removal of entrained air between the object and the PSA. In such a manner, a reflective OPV device (cell or module) is attached to a curved or three-dimensional object in such a way that the metal is located next to the object, to ensure light can reach the photoactive layer, regardless of the opacity of the object, to allow power generation.

A further exemplary embodiment of the invention comprises a method for the fabrication of a three-dimensional object, such as a curved window, with a semitransparent OPV, or SolarWindow™ device (cell or module) attached to its surface. SolarWindow™ is a photovoltaic window technology based upon semitransparent OPV that is the subject of several patent filings. A thin flexible substrate, such as a thin polymer foil, is attached to a more rigid yet still somewhat flexible support layer, such as a thick polymer foil, via a transfer release layer. The thin substrate is then coated with a TC material, as described previously. The TC layer is then coated with the remainder of the layers of a semitransparent OPV device, as is known to those skilled in the art of OPV. In some embodiments, the OPV device may be a conventional architecture OPV device, while in others it may be an inverted architecture OPV device, which has significant advantages for device lifetime. In either case, the photoactive layer, or BHJ, is chosen such that the light absorption of the materials ensures a reasonable degree of VLT and attractive aesthetics. In all cases, the final layer of the semitransparent OPV device includes another TC layer, such as PEDOT:PSS, rather than a metal layer. The TC layers must be chosen appropriately, along with the HCL and ECL layers, to ensure proper energy level alignment to ensure favorable electron and hole transport in the devices, as known to those skilled in the art. After the TC layer is deposited, as metal grid may be deposited as well, to aid in current collection/transport. As previously described, in some embodiments, additional processing steps may be performed to enable fabrication of series- and/or parallel-interconnected modules. After the semitransparent OPV device is completed, a PSA is applied to the surface of the device using coating techniques as known to those skilled in the art. The thin, flexible substrate along with the completed semitransparent OPV device and PSA are then removed from the rigid substrate using the release layer, and stretched and press-fit onto the curved or three-dimensional shape, with or without vacuum-assisted removal of entrained air between the object and the PSA. In such a manner, a semitransparent OPV device (cell or module) is attached to a three-dimensional object, such as a curved window, in such a way that light can pass through the object and the OPV device from either direction, while still generating power.

Other features and advantages of the present invention will become apparent to those skilled in the art upon review of the following detailed description and drawings.

### BRIEF DESCRIPTION OF THE DRAWINGS

These and other aspects and features of embodiments of the present invention will be better understood after a reading of the following detailed description, together with the attached drawings, wherein:

FIG. 1 is a cross-sectional view of a pressure-sensitive adhesive-coated optoelectronic device, itself coated on a thin flexible substrate with a transfer release layer and backing layer, which can be used to prepare planar and curved optoelectronic device-covered three-dimensional objects, according to an exemplary embodiment of this invention.

FIG. 2 is a cross-sectional view of a curved, three-dimensional solid object coated with a conformal optoelectronic device, prepared via the pressure-sensitive adhesive method, according to an exemplary embodiment of this invention.

FIG. 3 is a cross-sectional view of a curved, three-dimensional semitransparent object, such as a window, coated with a conformal optoelectronic device, prepared via the pressure-sensitive adhesive method, according to an exemplary embodiment of this invention.

FIG. 4 is a cross-sectional view of a curved, three-dimensional solid object coated with a conformal organic photovoltaic device, prepared via the pressure-sensitive adhesive method, according to an exemplary embodiment of this invention.

FIG. 5 is a cross-sectional view of a curved, three-dimensional semitransparent object, such as a window, coated with a conformal semitransparent organic photovoltaic device, prepared via the pressure-sensitive adhesive method, according to an exemplary embodiment of this invention.

### DETAILED DESCRIPTION OF THE EXEMPLARY EMBODIMENTS OF THE INVENTION

The present invention now is described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

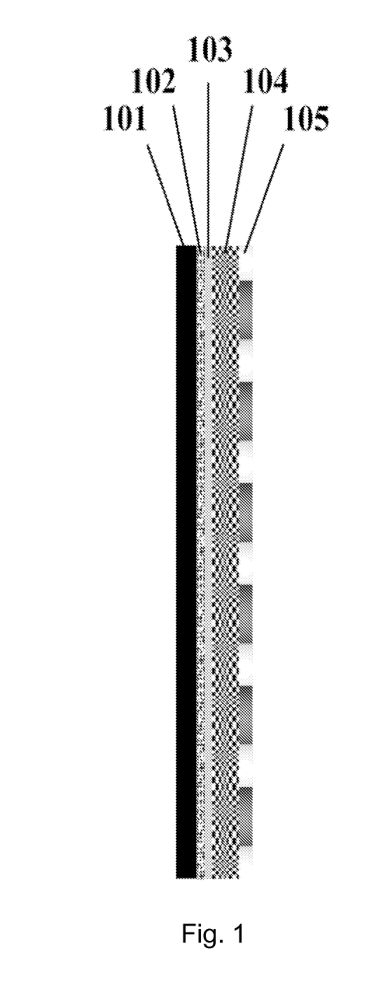

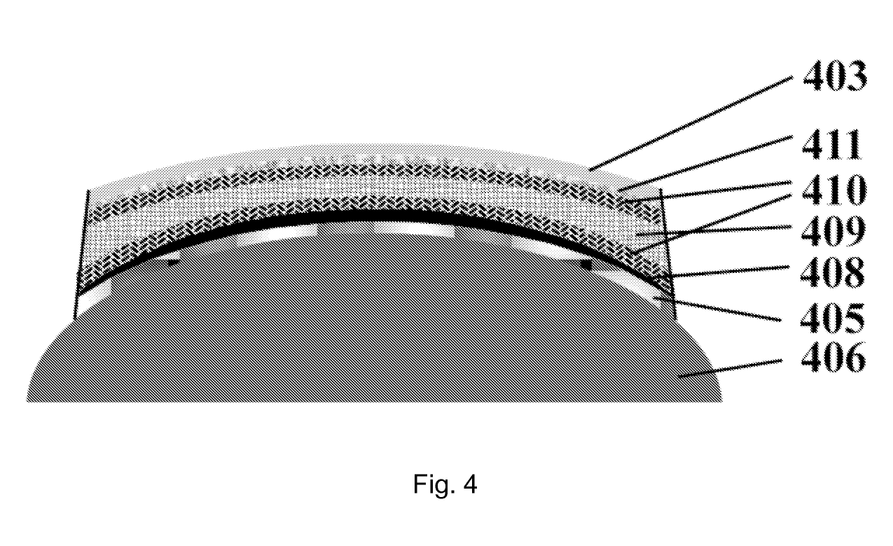

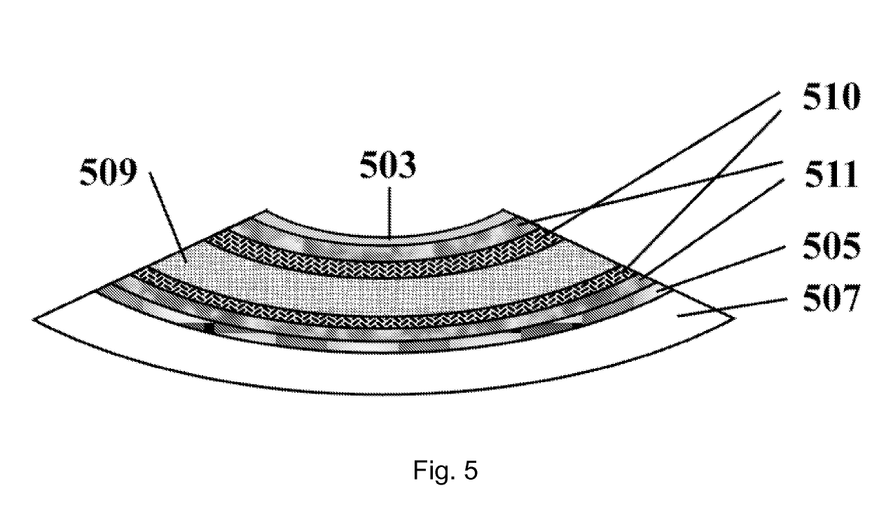

Referring now to the drawings, FIGS. 1-5 illustrate exemplary embodiments of the method for preparing three-dimensional objects coated with optoelectronic devices (FIGS. 1-3) and organic photovoltaic devices (FIGS. 4-5).

Referring to FIG. 1, which provides a cross-sectional view of a transfer film stack for the fabrication of organic optoelectronic device coatings for three-dimensional objects, the film is prepared upon a temporary base layer 101, in order to provide sufficient rigidity to allow conventional manufacturing techniques, including high-speed roll-to-roll coating. The base layer can include of glass or thick metal rigid substrates, flexible polymer or metal foils, or any convenient substrate material, depending on the chosen manufacturing methods. On top of the base layer is a transfer release layer 102 that allows easy removal of the base layer and transfer layer from the thin flexible substrate 103, which are all laminated together as known to those skilled in the art. The thin flexible substrate is any appropriate substrate material that is highly flexible and transparent, such as very thin polymer foils, including but not limited to polyethyleneterephthalate (PET). On top of this is coated an organic optoelectronic device, which may be any of a number of devices, including but not limited to: OPV and semi-transparent OPV devices (cells or modules), OLEDs, or organic electronic devices such as OTFTs, but which must be inherently flexible, and thus contain no highly crystalline materials. The coating and processing of these devices is known to those skilled in their respective arts, and in most cases is compatible with solution processing and high-throughput manufacturing techniques, including high-speed roll-to-roll or sheet-to-sheet production methods. The optoelectronic device is then coated with a pressure-sensitive adhesive 105 according to methods know to those skilled in the art. The resulting film comprising layers 101-105 can be used to transfer the optoelectronic device comprising layers 103-105 onto three-dimensional objects with arbitrary shapes and curvatures.

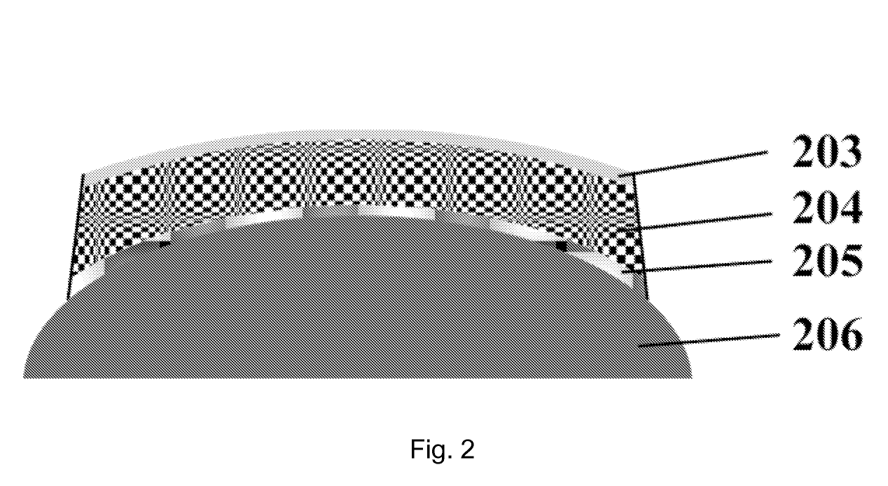

Referring to FIG. 2, which provides a cross-sectional view of a curved object coated with an organic optoelectronic device produced via the pressure-sensitive adhesive method, the base layer 206 includes an arbitrary solid object. Laminated onto the object using stretching and press-forming, with or without vacuum assistance in removing entrained air, is the optoelectronic device 204, which is adhered to the object using the pressure-sensitive adhesive layer 205, and is supported by the very thin, highly flexible substrate layer 203. The unique and inherent flexibility of organic optoelectronic devices allows lamination onto curved surfaces without significant disruption of device performance, and enables production of three-dimensional organic optoelectronic devices that would be difficult to produce via conventional coating techniques due to realities of capillarity flow on curved surfaces. This method enables organic optoelectronic devices to be laminated onto surfaces of arbitrary and changing curvature, which would be impossible via conventional solution coating techniques. While, in this exemplary embodiment, the method is necessarily a discrete process for the fabrication of each individual object, the intermediate transfer film (see FIG. 1) used to transfer the completed organic optoelectronic device onto the object can be produced in a continuous, high-throughput methodology. Not shown are any wires or other electrical contacts, or protective coatings that might prove beneficial.

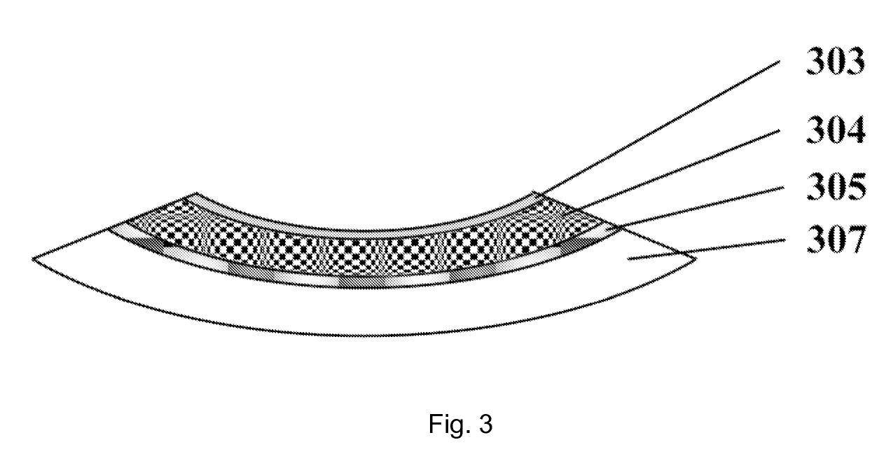

Referring to FIG. 3, which provides a cross-sectional view of a curved semitransparent object coated with an organic optoelectronic device produced via the pressure-sensitive adhesive method, the base layer 406 includes an arbitrary semitransparent object, such as a window. Laminated onto the object using stretching and press-forming, with or without vacuum assistance in removing entrained air, is the optoelectronic device 304, which is adhered to the object using the pressure-sensitive adhesive layer 305, and is supported by the very thin, highly flexible substrate layer 303. The unique and inherent flexibility of organic optoelectronic devices allows lamination onto curved surfaces without significant disruption of device performance, and enables production of three-dimensional organic optoelectronic devices that would be difficult to produce via conventional coating techniques due to realities of capillarity flow on curved surfaces. This method enables organic optoelectronic devices to be laminated onto surfaces of arbitrary and changing curvature, which would be impossible via conventional solution coating techniques. While, in this exemplary embodiment, the method is necessarily a discrete process for the fabrication of each individual object panel, the intermediate transfer film (see FIG. 1) used to transfer the completed organic optoelectronic device onto the object can be produced in a continuous, high-throughput methodology. Not shown are any wires or other electrical contacts, or protective coatings that might prove beneficial.

Referring to FIG. 4, which provides a cross-sectional view of a curved object coated with an OPV device, comprising one or more cells connecting in series and/or parallel, produced via the pressure-sensitive adhesive method, the base layer 406 includes an arbitrary solid object. Laminated onto the object via the pressure-sensitive adhesive 405 using stretching and press-forming, with or without vacuum assistance in removing entrained air, is the multilayer OPV device. Adhered directly to the base object is the metal electrode 408, which is ductile and reflective. On top of the metal electrode is a charge-collection layer 410 (hole or electron, depending on device polarity), which is used to make a selective contact to maximize OPV device performance, as known to those skilled in the art. These charge-collection layers are generally made of: transition metal oxides, which can be amorphous and thus flexible, or polymers or thin molecular layers, both of which are inherently flexible. In addition, these charge-collection layers can generally be made via high-throughput solution processed methods. On top of the first charge collection layer is the photoactive layer 409, generally a BHJ, which is generally made via solution techniques. On top of the BHJ is a second charge-collection layer 410, of opposite polarity as the previous collection layer. On top of the second charge-collection layer is a TC 411, to allow light to enter the device, while still transporting charge. Because the common TCO ITO is crystalline in nature, the TC must be an alternative material, one that is inherently flexible. Finally, on top is the very thin, highly flexible substrate 403. The unique and inherent flexibility of OPV devices allows lamination onto curved surfaces without significant disruption of device performance, and enables production of three-dimensional organic optoelectronic devices that would be difficult to produce via conventional coating techniques due to realities of capillarity flow on curved surfaces. This method enables OPV devices to be laminated onto surfaces of arbitrary and changing curvature, which would be impossible via conventional solution coating techniques. While, in this exemplary embodiment, the method is necessarily a discrete process for the fabrication of each individual object, the intermediate transfer film (see FIG. 1) used to transfer the completed OPV device onto the object can be produced in a continuous, high-throughput methodology. Not shown are any wires or other electrical contacts, or protective coatings that might prove beneficial.

Referring to FIG. 5, which provides a cross-sectional view of a curved semitransparent object coated with a semitransparent OPV device, comprising one or more cells connecting in series and/or parallel, produced via the pressure-sensitive adhesive method, the base layer 507 includes an arbitrary semitransparent object, such as a window. Laminated onto the object via the pressure-sensitive adhesive 405 using stretching and press-forming, with or without vacuum assistance in removing entrained air, is the multilayer semitransparent OPV device. To enable a semitransparent device, both electrodes 511 must be inherently flexible TCs; they can be identical, or different. On top of the first TC electrode is one of the charge-collection layers 510 (hole or electron, depending on device polarity). The photoactive (BHJ) layer 509, is sandwiched between the first and second charge collection layer, which, in this exemplary embodiment, necessarily must be different materials to ensure opposite polarity selectivity. On top of the second charge-collection layer 510, is the second TC 411. Finally, on top is the very thin, highly flexible substrate 503. The unique and inherent flexibility of OPV devices allows lamination onto curved surfaces without significant disruption of device performance, and enables production of three-dimensional organic optoelectronic devices that would be difficult to produce via conventional coating techniques due to realities of capillarity flow on curved surfaces. This method enables OPV devices to be laminated onto surfaces of arbitrary and changing curvature, which would be impossible via conventional solution coating techniques. While, in this exemplary embodiment, the method is necessarily a discrete process for the fabrication of each individual object, the intermediate transfer film (see FIG. 1) used to transfer the completed OPV device onto the object can be produced in a continuous, high-throughput methodology. Not shown are any wires or other electrical contacts, or protective coatings that might prove beneficial.

The present invention has been described herein in terms of several preferred embodiments. However, modifications and additions to these embodiments will become apparent to those of ordinary skill in the art upon a reading of the foregoing description. It is intended that all such modifications and additions comprise a part of the present invention to the extent that they fall within the scope of the several claims appended hereto.

What is claimed is:

1. A transfer film comprising:
a support substrate,
a transfer release layer laminated between the support substrate and
a very thin, highly flexible transparent substrate, such as PET,
a multilayer organic optoelectronic device,
and a pressure-sensitive adhesive

2. The transfer film of claim 1, wherein the support substrate is a rigid material such as glass or thick metal.

3. The transfer film of claim 1, wherein the support substrate is a flexible material, such as a polymer or metal foil compatible with roll-to-roll manufacturing techniques.

4. The transfer film of claim 1, wherein the optoelectronic device is semitransparent in nature.

5. The transfer film of claim 1, wherein the optoelectronic device is an organic photovoltaic device, comprising one or more cells connected in series and/or parallel.

6. The transfer film of claim 4, wherein the semitransparent optoelectronic device is a semitransparent organic photovoltaic device, comprising one or more cells connected in series and/or parallel.

7. A method for the manufacture of the flexible transfer film of claim 3, wherein:
the flexible foil is coated with the transfer release material,
laminated with the very thin, highly flexible transparent substrate, such as PET, coated with the multilayer organic optoelectronic device,
and coated with a pressure-sensitive adhesive,
all in a roll-to-roll manner,
and utilizing solution-processing,
to allow low-cost, high-throughput manufacturing.

8. A method for the manufacture of the flexible transfer film of claim 4, wherein:
the flexible foil is coated with the transfer release material,
laminated with the very thin, highly flexible transparent substrate, such as PET, coated with the semitransparent organic optoelectronic device,
and coated with a pressure-sensitive adhesive,
all in a roll-to-roll manner,
and utilizing solution-processing,
to allow low-cost, high-throughput manufacturing.

9. A method for the manufacture of the flexible transfer film of claim 5, wherein:
the flexible foil is coated with the transfer release material,
laminated with the very thin, highly flexible transparent substrate, such as PET, coated with the multilayer organic photovoltaic device,
and coated with a pressure-sensitive adhesive,
all in a roll-to-roll manner,
and utilizing solution-processing,
to allow low-cost, high-throughput manufacturing.

10. A method for the manufacture of the flexible transfer film of claim 6, wherein:
the flexible foil is coated with the transfer release material,
laminated with the very thin, highly flexible transparent substrate, such as PET, coated with the semitransparent organic photovoltaic device,
and coated with a pressure-sensitive adhesive,
all in a roll-to-roll manner,
and utilizing solution-processing,
to allow low-cost, high-throughput manufacturing.

11. A method for the manufacture of three-dimensional objects of arbitrary shape coated with organic optoelectronic devices comprising:
the manufacture of a transfer film according to the method of claim 7,
the conformal adhesion of the transfer film to the three-dimensional object using lamination, stretching, press-forming, and/or vacuum removal of entrained air,
and the removal of the support substrate and transfer release layer.

12. A method for the manufacture of semitransparent three-dimensional objects of arbitrary shape coated with semitransparent organic optoelectronic devices comprising:
the manufacture of a transfer film according to the method of claim 8,
the conformal adhesion of the transfer film to the semitransparent three-dimensional object using lamination, stretching, press-forming, and/or vacuum removal of entrained air,
and the removal of the support substrate and transfer release layer.

13. A method for the manufacture of three-dimensional objects of arbitrary shape coated with organic photovoltaic devices comprising:
the manufacture of a transfer film according to the method of claim 9,
the conformal adhesion of the transfer film to the three-dimensional object using lamination, stretching, press-forming, and/or vacuum removal of entrained air,
and the removal of the support substrate and transfer release layer.

14. A method for the manufacture of semitransparent three-dimensional objects of arbitrary shape coated with semitransparent organic photovoltaic devices comprising:
the manufacture of a transfer film according to the method of claim 10,
the conformal adhesion of the transfer film to the semitransparent three-dimensional object using lamination, stretching, press-forming, and/or vacuum removal of entrained air,
and the removal of the support substrate and transfer release layer.
